(19) United States
(12) Patent Application Publication
(10) Pub. No.: US 2016/0097118 A1
(43) Pub. Date: Apr. 7, 2016

(54) Inductively Coupled Plasma Enhanced Chemical Vapor Deposition

(71) Applicant: Seagate Technology LLC, Cupertino, CA (US)

(72) Inventors: Samuel L. Tanaka, Fremont, CA (US); Thomas L. Greenberg, Berkeley, CA (US); Christopher L. Platt, Fremont, CA (US); Joseph Tong, San Jose, CA (US)

(73) Assignee: Seagate Technology LLC

(21) Appl. No.: 14/798,570

(22) Filed: Jul. 14, 2015

Related U.S. Application Data
(60) Provisional application No. 62/058,310, filed on Oct. 1, 2014.

(51) Int. Cl. C23C 16/26; C23C 16/44; H01J 37/32; C23C 16/505

(52) U.S. Cl. CPC C23C 16/26; C23C 16/505; C23C 16/44; H01J 37/321

(57) ABSTRACT

A deposition system may have at least a substrate mounted within a sealed chamber. A radio frequency energy can be supplied to an inductive source affixed to the sealed chamber with the inductive source having an inductive coil surrounding a tube. Coupling the radio frequency energy into a gas pumped into the sealed chamber creates plasma to uniformly deposit a thin layer on a surface of the substrate.

### RELATED APPLICATION

The present application makes a claim of domestic priority to U.S. Provisional Patent Application No. 62/058,310 filed Oct.1, 2014, the contents of which are hereby incorporated by reference.

### SUMMARY

A deposition system, in accordance with various embodiments, mounts a substrate within a sealed chamber and supplies a radio frequency energy to an inductive source affixed to the sealed chamber with the inductive source having an inductive coil surrounding a tube. Coupling the radio frequency energy into a gas pumped into the sealed chamber creates plasma to uniformly deposit a thin layer on a surface of the substrate.

### BRIEF DESCRIPTION OF THE DRAWINGS

FIG. 1 is a line representation of an example deposition system configured and operated in accordance with various embodiments.

FIG. 2 shows a cross-sectional line representation of a portion of an example substrate configured in accordance with some embodiments.

FIG. 3 displays a line representation of a portion of an example deposition system arranged in accordance with assorted embodiments.

FIG. 4 is a flowchart of an example customer satisfaction routine that may be conducted in accordance with various embodiments.

### DETAILED DESCRIPTION

Without limitation, the present disclosure is generally directed to data storage media, and more particularly, systems and methods for forming overcoat layers on magnetic data recording media.

Controlling uniformity of a protective layer, such as a carbon overcoat (COC) layer, on a rotatable data recording medium can enhance mechanical and recording performance of the medium. An area of the medium having the relatively thinnest COC layer poses a risk of media corrosion, carbon-lube issues and durability performance. Moreover, it has been found that variations in the circumferential once-around (OAR) carbon thickness can adversely impact the bit error rate (BER) readback performance of the media.

Existing sources for carbon film deposition generally use a hot filament cathode to emit electrons by thermionic emission. Acceleration of the electrons results in a plasma in a chemical vapor deposition (CVD) media overcoat process. The plasma physics and surface chemistry (on all surfaces within the chamber, including the substrate) dictate the uniformity, deposition rate and properties of the resulting carbon thin films. While the hot filament design is an effective electron source, due to a number of factors such as aging and carburization, a filament can become unstable over time, which directly affects the carbon range performance and overall media quality.

Accordingly, various embodiments of the present disclosure are generally directed to the use of a so-called ACT (advanced carbon technology) source that uses inductively coupled plasma (ICP) in a plasma enhanced chemical vapor deposition (CVD) process. As explained below, an inductive coil operated at a suitable radio frequency (RF) generates couples into a gas in a deposition chamber to create plasma. The gas is cracked to direct deposition ions, such as carbon, onto a substrate. A dual-sided arrangement can be used so that protective overcoat layers, such as COC thin film layers, and other types of layers, can be concurrently formed on opposing sides of the substrate.

This advantageously eliminates the need for the use of carbon filaments and the associated control efforts associated with the filament, anode, gas flow, magnetic assemblies and shields that have heretofore been necessary to accommodate the deficiencies of the carbon filaments. It is contemplated that the various embodiments presented herein provide better, more uniform layer deposition with higher reliability and controllability.

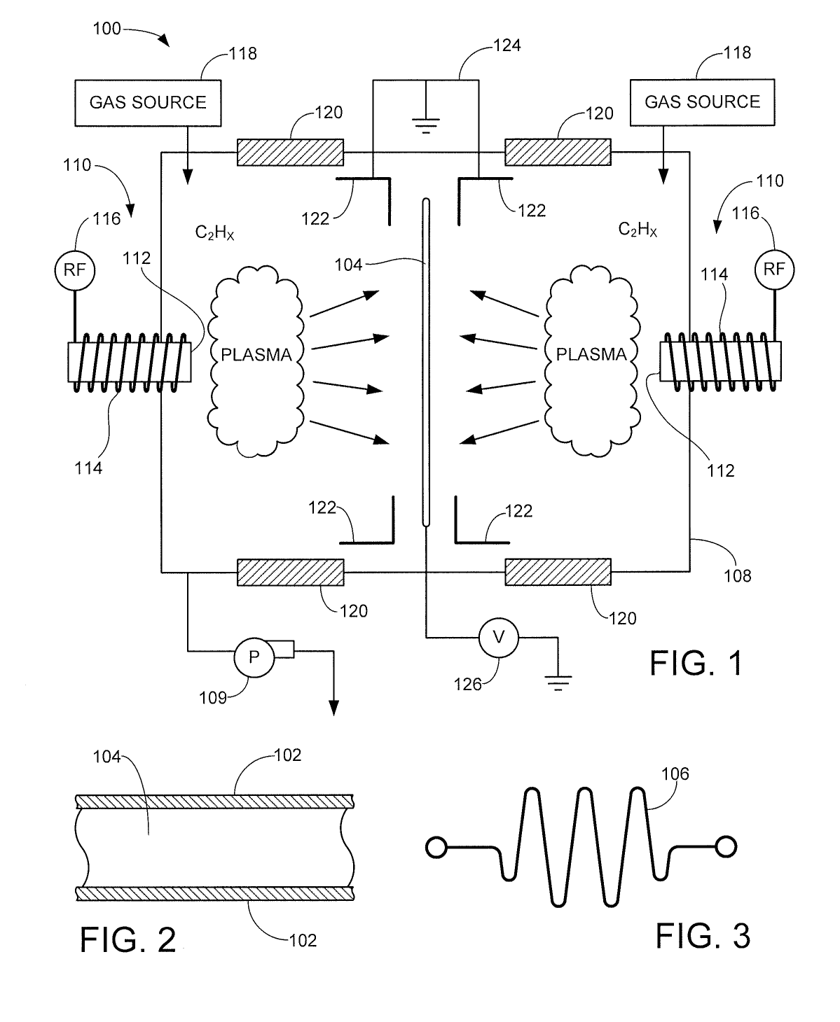

These and other features will become apparent beginning with a review of FIG. 1 which provides a schematic representation of an inductively coupled, plasma enhanced chemical vapor deposition (PECVD) system 100 constructed and operated in accordance with various embodiments. The system 100 is configured to deposit opposing thin films 102 onto an intervening substrate 104, as represented in FIG. 2.

The substrate 104 can take a variety of forms including but not limited to a rotatable data magnetic recording medium with various layers such as recording layers, interlayers, barrier layers, soft magnetic underlayers, heat sink layers, etc. Other forms of substrates can be used, however, including non-magnetic recording media. Moreover, while the system 100 is described in terms of depositing a protective layer, the skilled artisan can readily modify the system 100 to configure the system to deposit other layers of a recording medium as required.

For purposes of the present discussion, the thin films 102 will be contemplated as comprising carbon overcoat (COC) protective layers with a uniform thickness of nominally from about 3 angstroms, Å (3×10⁻¹⁰ meters, m) to about 20 Å. Other thicknesses and thickness ranges can be used as desired including but not limited to thicknesses of up to about 40 Å. It will be noted that the system 100 eliminates the need for the use of a carbon filament as an electron source to deposit the film material, as generally represented at 106 in FIG. 3. While double-sided deposition is contemplated, such is not necessarily required in that the various aspects of the system 100 can be modified to deposit thin film layers on only a single side of the substrate 104.

Referring again to FIG. 1, the substrate 104 is supported within a specially configured, chemical vapor deposition (CVD) chamber 108. A pump (P) assembly 109 is adapted to establish and maintain an interior environment at a suitable vacuum pressure.

A pair of inductive sources 110 is shown to provide the energy to enact the deposition process. Each of the inductive sources 110 include a tube (barrel) 112 surrounded by an inductive coil 114. The coils 114 are driven by respective radio frequency (RF) sources 116. A suitable RF frequency at an input power level of up to about 500 watts, W is applied.

A pair of gas sources 118 provides an inlet flow of gas into the chamber 108. While shown separately in FIG. 1 for clarity of illustration, in some embodiments the inlet flows of gas from the sources 118 are directed through the respective tubes 112 into the interior of the chamber 108. Any suitable gas can be used, such as a hydrocarbon gas (e.g., C₂Hₓ, etc.).

The gas takes a plasma state from the excitation provided by the inductive sources 110, directing ions (in this case, carbon) to the substrate 104. Magnet assemblies 120 and shields 122 can be used to control the ionic flow and deposition process. The shields may be grounded via reference voltage connection path 124. In some cases, a negative voltage bias can be applied to the substrate 104 to enhance and control the deposition process. The bias voltage is supplied by a direct current (DC) voltage source 126. Any suitable voltage can be used, such as nominally −120 VDC. Other features (not separately illustrated) can be incorporated into the system 100 including cooling systems, cathode and/or anode plates or structures, etc.

It will be appreciated that the various embodiments disclosed herein can provide a number of benefits. The system eliminates the need to use a separate filament member (such as 106, FIG. 3). In some cases, the inductive sources 110 can be incorporated into existing CVD chambers and use existing elements such as cooling plates, magnet rings, anodes, substrate support and bias mechanisms, venting systems, etc.

The tube length, material, number of windings, etc. Can be varied based on application requirements. Gas injection through the central tube provides uniform presentation and flow of the ions to the substrate. Different RF frequencies can be tuned for particular applications.

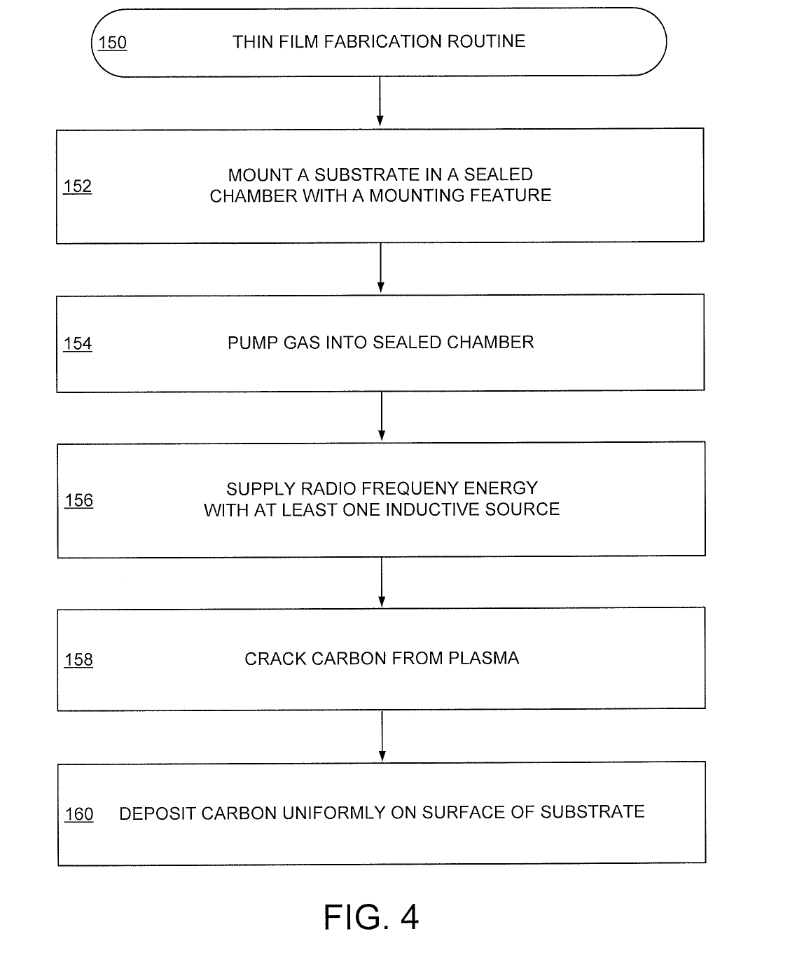

FIG. 4 provides a flowchart of an example thin film fabrication routine 150 that can be carried out with a deposition system in accordance with various embodiments. The fabrication routine 150 begins by providing a sealed chamber with at least one inductive source affixed thereon. Step 152 mounts at least one substrate in the sealed chamber via a mounting feature, such as clamps or fasteners. The sealed chamber is partially or completely filled with a hydrocarbon gas in step 154.

Next, step 156 supplies radio frequency energy with the inductive coil of an inductive source to form plasma. The plasma is subsequently cracked in step 158 to release carbon from the hydrocarbon plasma before depositing the elemental carbon uniformly on a surface of the substrate. As a result of routine 150, a thin layer of carbon is formed on the substrate with a uniform thickness, which optimizes substrate performance in assorted data storage environments. It is noted that the various steps of routine 150 are not required or limiting. As such, any aspect of routine 150 can be altered or removed and additional steps and decisions can be added.

It is to be understood that even though numerous characteristics of various embodiments of the present disclosure have been set forth in the foregoing description, together with details of the structure and function of various embodiments, this detailed description is illustrative only, and changes may be made in detail, especially in matters of structure and arrangements of parts within the principles of the present technology to the full extent indicated by the broad general meaning of the terms in which the appended claims are expressed. For example, the particular elements may vary depending on the particular application without departing from the spirit and scope of the present disclosure.

What is claimed is:

1. An apparatus comprising:
a sealed chamber housing a substrate; and
means for uniformly depositing a carbon layer on opposite sides of the substrate.

2. The apparatus of claim 1, wherein the means for uniformly depositing a carbon layer emits electrons without a filament.

3. The apparatus of claim 1, wherein the means for uniformly depositing a carbon layer comprises an inductive coil supplied with a radio frequency.

4. The apparatus of claim 1, wherein the means for uniformly depositing a carbon layer comprises an inductive coil facing opposite sides of the substrate.

5. The apparatus of claim 1, wherein the means for uniformly depositing a carbon layer extends from within the sealed chamber to outside the sealed chamber.

6. The apparatus of claim 1, wherein the means for uniformly depositing a carbon layer is positioned between at least two magnets and at least two shields.

7. A method comprising:
mounting a substrate within a sealed chamber;
supplying a radio frequency energy to a first inductive source affixed to the sealed chamber, the first inductive source comprising an inductive coil surrounding a tube;
pumping a gas into the sealed chamber; and
coupling the radio frequency energy into the gas with the first inductive source to form a plasma to uniformly deposit a first thin layer on a first surface of the substrate.

8. The method of claim 7, wherein a second inductive source is affixed to the sealed chamber and deposits a second thin layer onto a second surface of the substrate.

9. The method of claim 7, wherein the first thin layer comprises carbon.

10. The method of claim 7, wherein the gas is a hydrocarbon.

11. The method of claim 7, wherein the sealed chamber comprises at least one shield connected to an electrical ground.

12. An apparatus, comprising:
a sealed deposition chamber having a mounting feature to support a substrate therein; and
an inductive source comprising a source of radio frequency (RF) energy, a tube and an inductive coil which surrounds the tube, the RF energy coupled into a gas by the inductive source to create a plasma to deposit a thin layer on the substrate.

13. The apparatus of claim 12, the inductive source further comprising a gas source which injects a gas through the tube into the chamber.

14. The apparatus of claim 13, the gas comprising a hydrocarbon gas, the thin layer comprising a protective carbon overcoat (COC).

15. The apparatus of claim 12, the inductive source comprising a first inductive source, the apparatus further comprising a second inductive source nominally identical to the first inductive source, the first and second inductive sources arranged on opposing sides of the substrate to concurrently form respective first and second thin films thereon.

16. The apparatus of claim 12, the RF energy supplied at an RF frequency with an input power level of up to about 500 watts, W.

17. The apparatus of claim 12, further comprising a bias source that applies a negative bias voltage to the substrate.

18. The apparatus of claim 12, further comprising a magnet assembly which surrounds the plasma within the chamber.

19. The apparatus of claim 12, further comprising a shield between the inductive source and the substrate to control deposition thickness of the thin film.

20. The apparatus of claim 12, the thin film comprising a layer of carbon having a thickness of from about 3 Å to about 40 Å.
